(19) United States
(12) Patent Application Publication
(10) Pub. No.: US 2026/0362835 A1
(43) Pub. Date: Nov. 12, 2026

(54) IMAGE SENSING DEVICE AND MANUFACTURING METHOD OF THE SAME

(71) Applicant: SK hynix Inc., Icheon-si (KR)

(72) Inventor: Woo Yung JUNG, Icheon-si (KR)

(21) Appl. No.: 19/380,728

(22) Filed: Nov. 5, 2025

(30) Foreign Application Priority Data
May 9, 2025 (KR) 10-2025-0060416

(51) Int. Cl. H10F 39/00

(52) U.S. Cl. CPC H10F 39/8053; H10F 39/024; H10F 39/8057

(57) ABSTRACT

An image sensing device includes a substrate; a pixel array supported by the substrate and configured to include pixels; a shield region supported by the substrate and disposed outside the pixel array; a plurality of color filters disposed over the substrate; a first grid structure disposed between color filters in the pixel array; a second grid structure connected to the first grid structure and disposed between color filters in the shield region; and a light absorption layer disposed between the substrate and the second grid structure in the shield region, wherein the second grid structure includes an open grid region having an upper portion open to expose an internal region of the second grid structure.

### CROSS-REFERENCE TO RELATED APPLICATION

This patent document claims the priority and benefits of Korean patent application No. 10-2025-0060416, filed on May 09, 2025, which is incorporated by reference in its entirety as part of the disclosure of this patent document.

### TECHNICAL FIELD

The technology and implementations disclosed in this patent document generally relate to an image sensing device.

### BACKGROUND

An image sensor is a device for capturing optical images by converting light into electrical signals using a photosensitive semiconductor material which reacts to light. With the recent development of computer and communication industries, the demand for high-performance image sensors is increasing in various fields such as digital cameras, camcorders, personal communication systems (PCSs), game consoles, robots, surveillance cameras, medical micro cameras, etc.

### SUMMARY

Various embodiments of the disclosed technology relate to an image sensing device capable of increasing the reliability of a grid structure including an air layer.

In accordance with an embodiment of the disclosed technology, an image sensing device may include: a substrate; a pixel array supported by the substrate and configured to include pixels; a shield region supported by the substrate and disposed outside the pixel array; a plurality of color filters disposed over the substrate; a first grid structure disposed between color filters in the pixel array; a second grid structure connected to the first grid structure and disposed between color filters in the shield region; and a light absorption layer disposed between the substrate and the second grid structure in the shield region, wherein the second grid structure includes an open grid region having an upper portion open to expose an internal region of the second grid structure.

In accordance with another embodiment of the disclosed technology, a method for manufacturing an image sensing device may include: forming a light absorption layer in a shield region supported by a substrate including a pixel array, the shield region disposed outside the pixel array; forming a first sacrificial layer over the substrate and the light absorption layer; forming a first mask pattern over the first sacrificial layer to define a region in which a grid structure is to be formed; etching the first sacrificial layer using the first mask pattern as an etch mask to form at least one sacrificial layer pattern in each of the pixel array and the shield region; forming at least one first capping layer to cover the sacrificial layer pattern; exposing the sacrificial layer pattern by selectively removing an upper portion of the first capping layer located in the shield region; and removing the sacrificial layer pattern.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some embodiments of the disclosed technology.

FIG. 2 is a plan view illustrating an example of a grid structure formed in a pixel region shown in FIG. 1 based on some embodiments of the disclosed technology.

FIG. 3 is a cross-sectional view illustrating an example of a cross-section of the grid structure taken along the line X-X’ shown in FIG. 2 based on some embodiments of the disclosed technology.

FIG. 4 is a plan view illustrating an example of appearance of a grid structure formed in the pixel region shown in FIG. 1 based on some embodiments of the disclosed technology.

FIGS. 5A-5G are cross-sectional views illustrating examples of a method for forming the structure shown in FIG. 3 based on some embodiments of the disclosed technology.

FIGS. 6A and 6B are cross-sectional views illustrating examples of another method for forming the structure shown in FIG. 3 based on some embodiments of the disclosed technology.

FIG. 7 is a cross-sectional view illustrating an example of a cross-section of the grid structure taken along the line X-X’ shown in FIG. 2 based on some embodiments of the disclosed technology.

FIG. 8 is a cross-sectional view illustrating an example of a cross-section of the grid structure taken along the line X-X’ shown in FIG. 2 based on some embodiments of the disclosed technology.

FIGS. 9A-9I are cross-sectional views illustrating examples of a method for forming the structure shown in FIG. 8 based on some embodiments of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device that can increase the reliability of a grid structure including an air layer. In recognition of the issues above, the disclosed technology provides various implementations of the image sensing device that can increase the reliability of a grid structure including an air layer.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

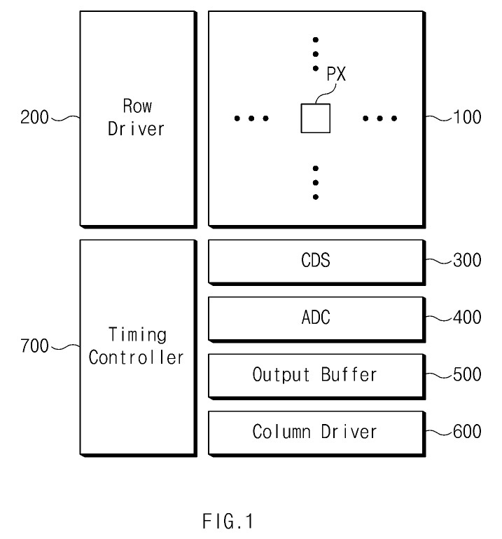

FIG. 1 is a block diagram illustrating an example of an image sensing device based on some embodiments of the disclosed technology.

Referring to FIG. 1, the image sensing device may include a pixel region 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel region 100 may include a plurality of unit pixels (PXs) consecutively arranged in a two-dimensional (2D) structure. The unit pixels (PXs) may convert incident light into electrical signals corresponding to the incident light, and may generate pixel signals. The pixel region 100 may include a grid structure disposed between color filters of adjacent unit pixels to prevent crosstalk between the color filters of the adjacent unit pixels. The grid structure may include an air layer.

The row driver 200 may select one or more unit pixels connected to at least one row line of the pixel region 100 based on control signals received from a control circuit such as the timing controller 700.

The correlated double sampler (CDS) 300 may remove undesired offset values of the unit pixels using correlated double sampling.

The ADC 400 may convert the CDS signal received from the correlated double sampler (CDS) 300 into a digital signal.

The output buffer 500 may temporarily store column-based data received from the ADC 400 under the control of the timing controller 700.

The column driver 600 may select a column of the output buffer 500 under the control of the timing controller 700, and may sequentially output data temporarily stored in the selected column of the output buffer 500.

The timing controller 700 may generate signals for controlling operations of the row driver 200, the ADC 400, the output buffer 500 and the column driver 600.

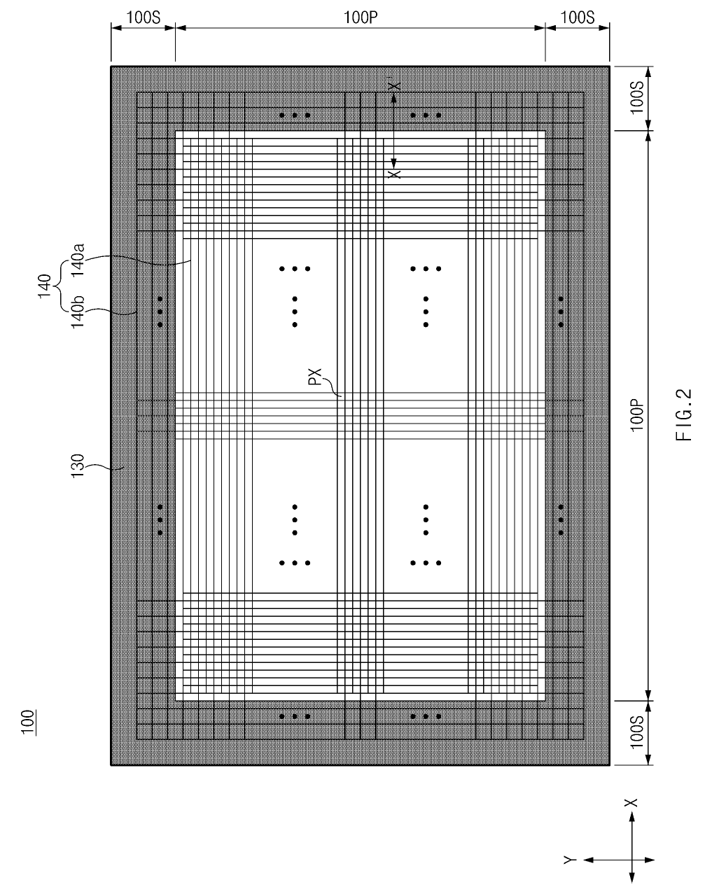

FIG. 2 is a plan view illustrating an example of a grid structure formed in the pixel region 100 shown in FIG. 1 based on some embodiments of the disclosed technology.

Referring to FIG. 2, the pixel region 100 may include a pixel array 100P and a shield region 100S disposed outside of the pixel array 100P.

The pixel array 100P may be formed in a square shape at the center of the pixel region 100. The pixel array 100P may include a plurality of unit pixels (PXs) arranged in a first direction (e.g., X-axis direction) and a second direction (e.g., Y-axis direction) intersecting the first direction.

The pixel array 100P may include an effective pixel array for image generation and a plurality of dummy pixels located outside the effective pixel array. The effective pixel array may include imaging or effective pixels that detect incident light for capturing images in response to incident light. The imaging or effective pixels produce photocharges in response to received incident light to represent the image information of the image carried by the incident light. Unlike the effective or imaging pixels, the dummy pixels are not used for capturing images in the incident light. The unit pixels (PXs) may include color filters, and a grid structure 140 may be formed between the color filters of adjacent unit pixels to prevent optical crosstalk between the color filters. The grid structure 140 may include a structure that encloses an air layer.

A shield region 100S may be formed outside the pixel array 100P to prevent incident light from entering the substrate. The shield region 100S may include a light absorption layer 130 for absorbing the incident light. The light absorption layer 130 may include a metal (e.g., tungsten), and may be formed over the substrate.

The grid structure 140 may be formed not only in the pixel array 100P but also to extend into the shield region 100S. The grid structure 140 may include a first grid structure 140b disposed in the pixel array 100P and a second grid structure 140b disposed over the light absorption layer 130 in the shield region 100S. Each of the first grid structure 140b and the second grid structure 140b may include a plurality of first patterns extending in a line shape in the first direction and arranged in parallel to each other and a plurality of second patterns extending in a line shape in the second direction and arranged in parallel to each other. The first patterns and the second patterns of each of the first grid structure 140a and the second grid structure 140b are disposed to cross each other.

In some implementations, the second grid structure 140b may be connected to end portions of some of the first and second patterns of the first grid structure 140a. For example, the second grid structure 140b may be connected to the first and second patterns of the first grid structure 140a at regular intervals. In FIG. 2, the second grid structure 140b may be connected to the even-numbered (or odd-numbered) first patterns of the first grid structure 140a, and may be connected to the even-numbered (or odd-numbered) second patterns of the first grid structure 140a, without being limited thereto. In some implementations, the second grid structure 140b may be connected to the end portions of all of the first and second patterns of the first grid structure 140a.

The spacing between the first patterns of the second grid structure 140b may be greater than the spacing between the first patterns of the first grid structure 140a, and the spacing between the second patterns of the second grid structure 140b may be greater than the spacing between the second patterns of the first grid structure 140a. For example, the spacing between the first patterns of the second grid structure 140b may be at least twice the spacing between the first patterns of the first grid structure 140a, and the spacing between the second patterns of the second grid structure 140b may be at least twice the spacing between the second patterns of the first grid structure 140a. Alternatively, the patterns of the second grid structure 140b may also be arranged at the same intervals as those of the first grid structure 140a.

The first grid structure 140a may be or include an air grid structure that includes an air layer and the air grid structure is formed by a capping layer covering the side and upper portions of the air layer. In the first grid structure 140b, the air layers of the first patterns and the air layers of the second patterns may be connected to each other. The second grid structure 140b may include a capping layer having an open upper portion.

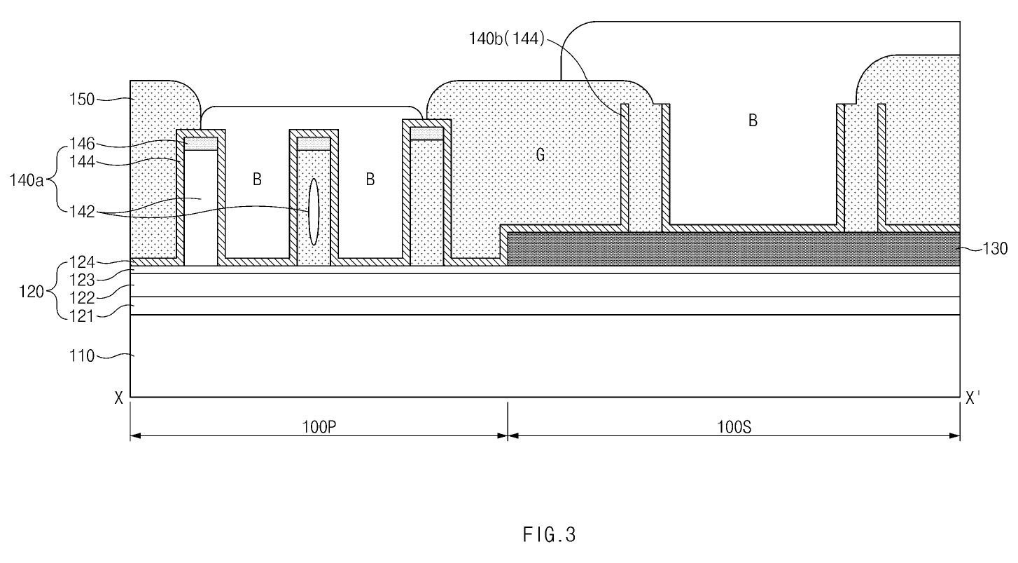

FIG. 3 is a cross-sectional view illustrating an example of a cross-section of the grid structure taken along the line X-X’ shown in FIG. 2 based on some embodiments of the disclosed technology.

Referring to FIG. 3, the pixel region 100 of the image sensing device may include a substrate 110, a buffer layer 120, a light absorption layer 130, a first grid structure 140a, a second grid structure 140b, and color filters 150.

The substrate 110 may include a semiconductor substrate having a first surface and a second surface facing or opposite to the first surface. The substrate 110 may include a pixel array 100P and a shield region 100S disposed outside the pixel array 100P.

The first surface of the substrate 110 may be a surface upon which light is incident. In the pixel array 100P, a buffer layer 120, the first grid structure 140a, and color filters 150 may be formed over the first surface. In the shield region 100S, a buffer layer 120, a light absorption layer 130, the second grid structure 140b, and color filters 150 may be formed over the first surface. A plurality of photoelectric conversion elements and a pixel isolation structure disposed between the photoelectric conversion elements may be formed in the substrate 112.

The buffer layer 120 may be disposed below the color filters 150 over the first surface of the substrate 110. The buffer layer 120 may operate as a planarization layer to remove a step difference formed over the first surface of the substrate 110. In some implementations, the buffer layer 120 may operate as an anti-reflection layer to allow incident light to pass through the photoelectric conversion elements.

The buffer layer 120 may include a multilayer structure formed by stacking an oxide layer and a nitride layer. For example, the buffer layer 120 may include first to fourth buffer layers (121, 122, 123, 124). The first buffer layer 121 may include a metal oxide layer such as aluminum oxide (Al₂O₃) or hafnium oxide (HfO₂). The second buffer layer 122 may include silicon oxide (SiO₂), and the third buffer layer 123 may include a nitride layer such as silicon nitride or silicon oxynitride. The fourth buffer layer 124 may include a material same as that of the first capping layer 144 of the grid structures (140a, 140b), and may be formed simultaneously with the first capping layer 144. For example, the fourth buffer layer 124 may be formed such that the first capping layer 144 extends beneath the color filter 150. The fourth buffer layer 124 may include an ultra-low temperature oxide (ULTO) layer such as a silicon oxide (SiO₂) layer.

The light absorption layer 130 may be disposed over the first surface of the substrate 110 in the shield region 100S to prevent incident light from entering the substrate 110 in the shield region 100S. For example, the light absorption layer 130 may be disposed over the third buffer layer 123 and beneath the fourth buffer layer 124 and the second grid structure 140b. The light absorption layer 130 may include a metal (e.g., tungsten).

The first grid structure 140a and the second grid structure 140b may be disposed between the color filters 150 to prevent crosstalk of incident light between the color filters 150. The first grid structure 140b may be disposed between the color filters 150 in the pixel array 100P, and the second grid structure 140b may be disposed between the color filters 150 in the shield region 100S.

In the example in FIG. 3, the first grid structure 140a may include an air layer 142, a first capping layer 144, and a support layer 146.

The air layer 142 may be formed in a region defined by the first capping layer 144. In FIG. 3, the air layer 142 is shown as being located over the third buffer layer 123, without being limited thereto. Alternatively, the air layer 142 may extend downward to a depth at which the air layer 142 penetrates the first to third buffer layers (121~123), thereby preventing incident light from causing crosstalk through the buffer layers (121~123).

The first capping layer 144 may be formed to provide the space to support the air layer 142 and to surround the air layer 142. For example, the first capping layer 144 may be formed to cover the top and side surfaces of the air layer 142, thereby preventing the air layer 142 from being exposed to the outside. The first capping layer 144 may include an ultra-low-temperature oxide (ULTO) layer.

The support layer 146 may be disposed over the air layer 142 so as to contact the top surface of the first capping layer 144. The support layer 146 may support the first capping layer 144 during the formation of the air layer 142. The support layer 146 may include an insulation layer without having light absorption capabilities. For example, the support layer 146 may be an insulation layer with a different etch selectivity from a spin on carbon (SOC) layer containing carbon, and may include a silicon oxynitride (SiON) layer. In some implementations, the support layer 146 may be omitted.

The second grid structure 140b may include the first capping layer 144 having an upper region open or exposed. For example, the second grid structure 140b may be formed in a structure where the top surface of the second grid structure 140b is removed so that the second grid structure 140b does not contain an air layer 142. In the implementation, the first capping layers 144 are formed as sidewalls spaced apart from each other by a predetermined distance. A color filter material may be formed or disposed between two sidewalls of the second grid structure 140b. For example, in comparison to the first grid structure 140a having the support layer 146 contacting the top surface of the first capping layer 144, the second grid structures 140b may be configured without the support layer and the first capping layers 144 are formed with sidewalls only without top surfaces of the first capping layers 144. Thus, the inner region of each of the second grid structures 140b is opened or exposed. As a result, the color filter material may flow into the open or exposed space between two sidewalls of the second grid structure 140b during the formation of the color filter 150.

Although FIG. 3 illustrates a case where the upper region of the second grid structure 140b is entirely removed, other implementations are also possible. For example, in some implementations, only a partial region of the second grid structure 140b may be formed in an open grid structure with the upper region removed. In the example, the open grid structure may refer to the gird structure having an upper region removed and thus exposed to outside. For example, the second grid structure 140b may be formed entirely as an open grid region, or only some portions of the second grid structure 140b may be formed as open grid regions while the remaining portion of the second grid structure 140b may have un-open upper regions. In this case, the open grid region may refer to a region in which the second grid structure 140b is formed with the open grid structure.

The open grid region may be a region that is adjacent to the pixel array 100P in the shield region 100S, or may be an edge region of the shield region 100S. The open grid region may be formed in a rectangular band shape surrounding the pixel array 100P.

In the first grid structure 140a located at the edge region of the pixel array 100P, a color filter material may be formed instead of an air layer. For example, since the first grid structure 140b and the second grid structure 140b are connected to each other, the color filter material flowing into the second grid structure 140b may also flow into the air layer region of the first grid structure 140a located at the edge region of the pixel array 100P.

The color filters 150 may be formed in regions defined by the first grid structure 140a and the second grid structure 140b within the pixel array 100P and the shield region 100S. The color filters 150 may filter incident light by color and allow the filtered light to pass therethrough. The color filters 150 may include a plurality of red color filters (not shown), a plurality of green color filters (G), and a plurality of blue color filters (B).

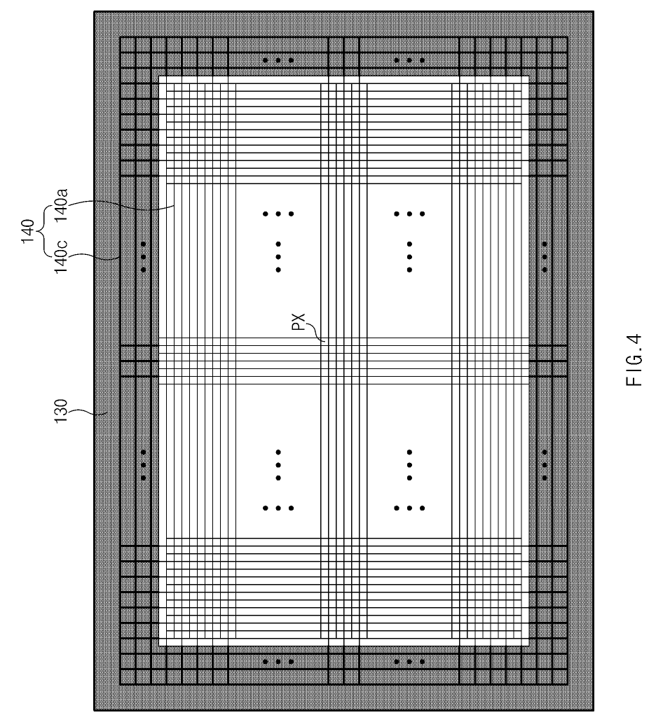

FIG. 4 is a plan view illustrating another example of a grid structure formed in the pixel region shown in FIG. 1 based on some embodiments of the disclosed technology.

Referring to FIG. 4, the grid structure 140 may include a first grid structure 140b and a second grid structure 140c. Compared to the grid structure shown in FIG. 2, the grid structure 140 of FIG. 4 may include the first grid structure 140b and the second grid structure 140c having with different widths from each other. For example, the second grid structure 140c may be formed with a greater width than the first grid structure 140a.

The remaining structures other than the second grid structure 140c of FIG. 4 are the same as those of FIG. 2, and as such redundant description thereof will herein be omitted for brevity.

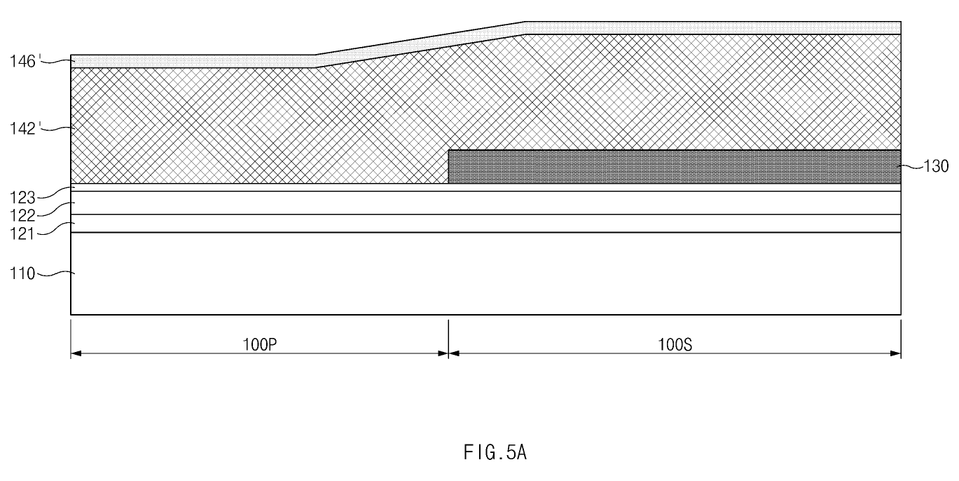

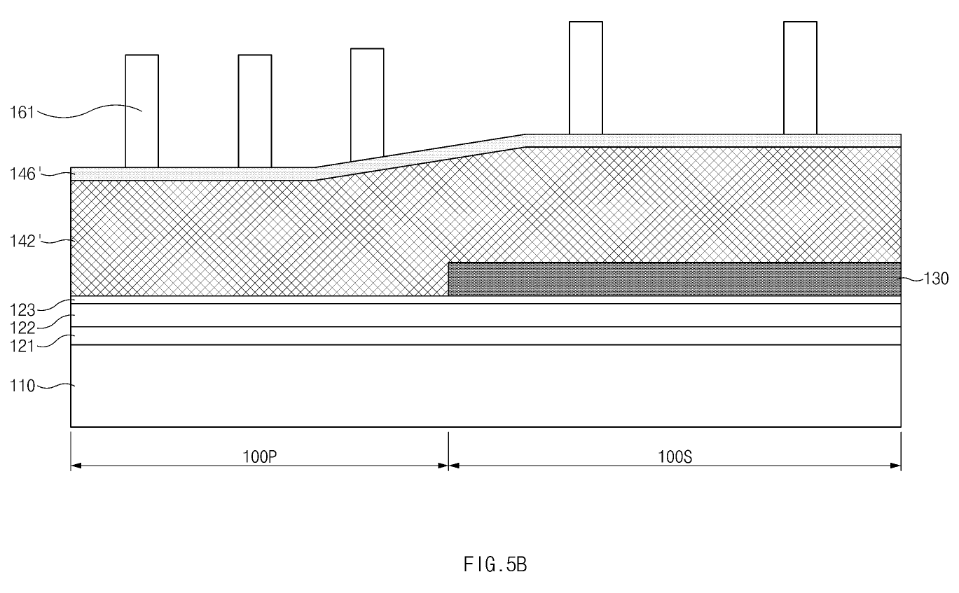

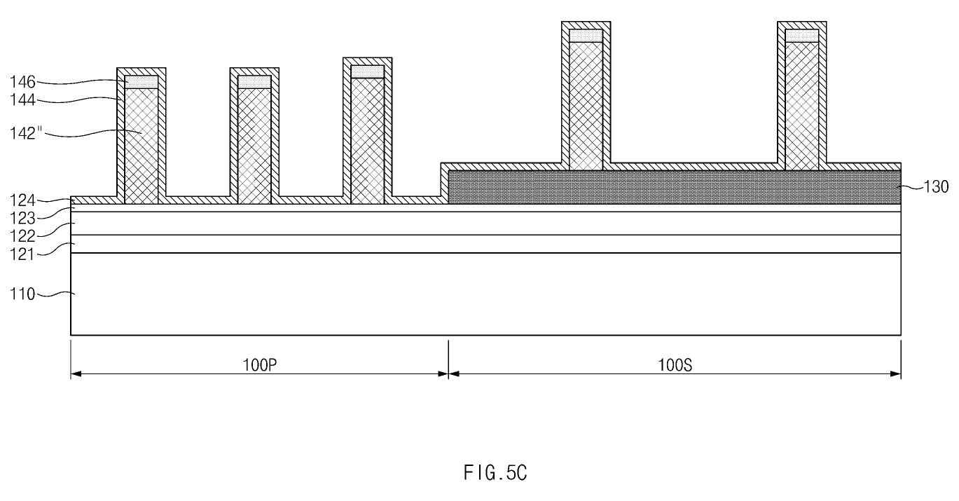

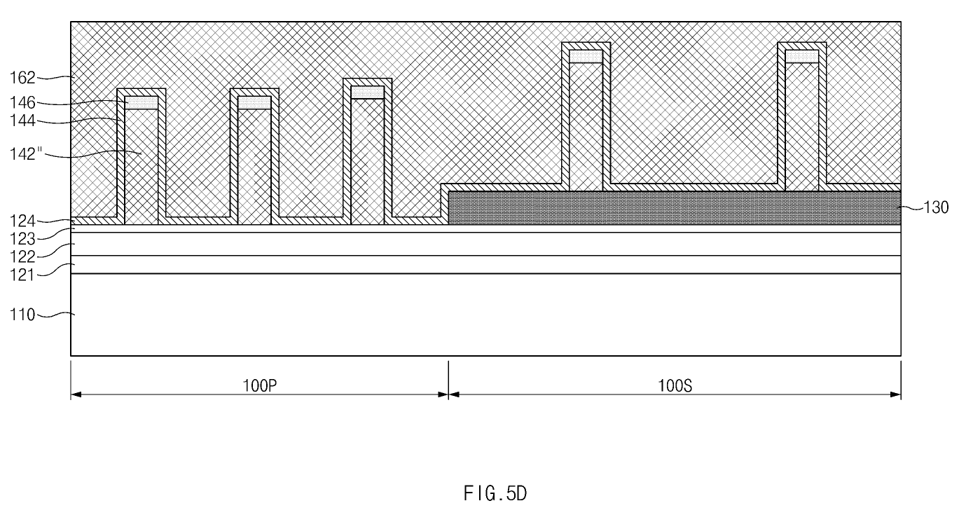

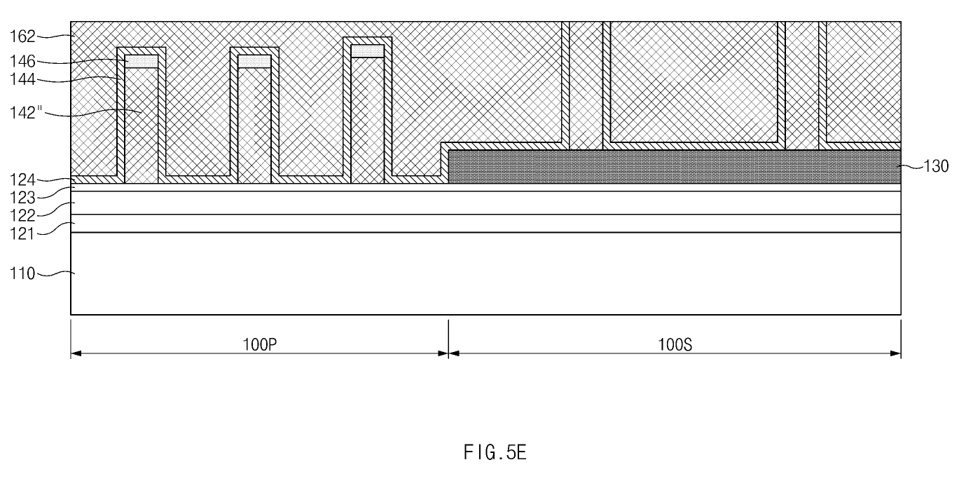

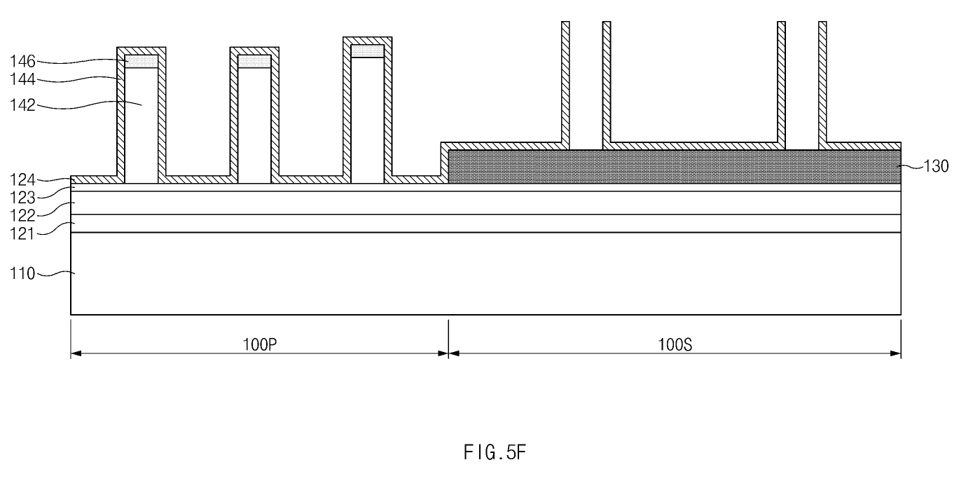

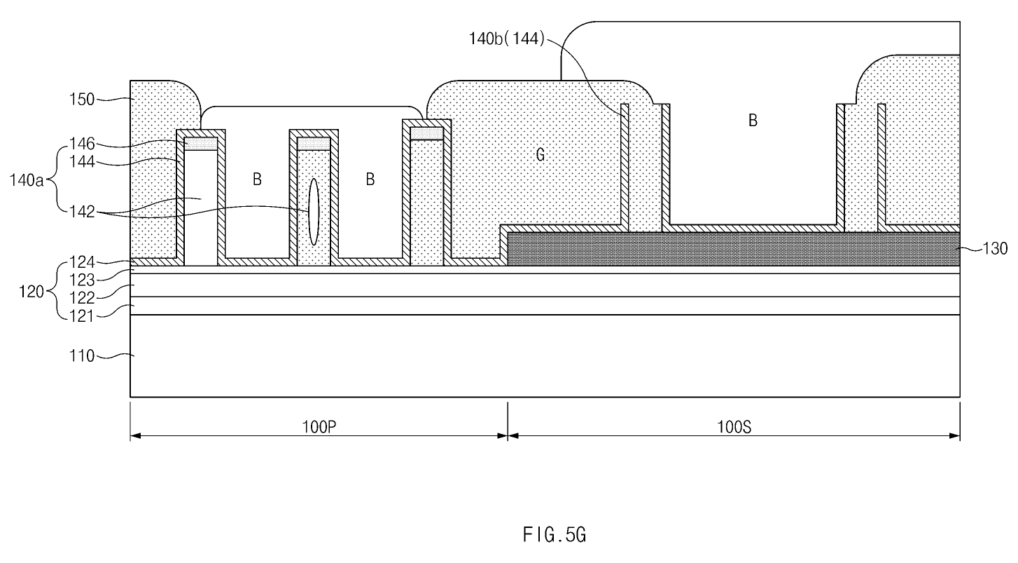

FIGS. 5A-5G are cross-sectional views illustrating examples of a method for forming the structure shown in FIG. 3 based on some embodiments of the disclosed technology.

Referring to FIG. 5A, first to third buffer layers (121~123) may be sequentially formed over the substrate 110 in which photoelectric conversion elements and at least one pixel isolation structure is formed. In this case, the first buffer layer 121 may include a metal oxide such as aluminum oxide (Al₂O₃) or hafnium oxide (HfO₂). The second buffer layer 122 may include silicon oxide (SiO₂), and the third buffer layer 123 may include a nitride layer such as silicon nitride or silicon oxynitride.

Subsequently, after a metal layer is formed over the third buffer layer 123, the metal layer may be patterned so that it remains only in the shield region 100S, resulting in formation of the light absorption layer 130.

In both the pixel array 100P and the shield region 100S, a sacrificial layer 142’ may be formed over the third buffer layer 123 and the light absorption layer 130, and a support material layer 146’ may be formed over the sacrificial layer 142’. In this case, since a step difference between the pixel array 100P and the shield region 100S occurs due to the light absorption layer 130, the sacrificial layer 142’ of the shield region 100S may be located higher than the sacrificial layer 142’ of the pixel array 100P. The sacrificial layer 142’ may include a spin-on carbon (SOC) layer containing carbon, and the support material layer 146’ may include silicon oxynitride (SiON).

Referring to FIG. 5B, at least one mask pattern 161 may be formed over the support material layer 146’ to define the regions where the first grid structure 140a and the second grid structure 140b are to be formed. For example, the mask patterns 161 may define the regions to be capped by the first capping layer 144, and may be connected to each other in a grid shape within the pixel array 100P and the shield region 100S, as in the grid structures 140 of FIGS. 2 or 4. The mask pattern 161 may include a photoresist pattern.

Referring to FIG. 5C, the support material layer 146’ and the sacrificial layer 142’ may be sequentially etched (patterned) using the mask pattern 161 as an etch mask, resulting in formation of the support layer 146 and the sacrificial layer pattern 142”.

Thereafter, a fourth buffer layer 124 and a first capping layer 144 may be formed to cover the third buffer layer 123, the light absorption layer 130, the sacrificial layer pattern 142”, and the support layer 146. The fourth buffer layer 124 and the first capping layer 144 may include an ultra-low-temperature oxide (ULTO) layer. Although the present embodiment has disclosed that the fourth buffer layer 124 and the first capping layer 144 are shown separately for convenience of description, other implementations are also possible, and it should be noted that the fourth buffer layer 124 and the first capping layer 144 may also be formed simultaneously through the same process.

Referring to FIG. 5D, a sacrificial layer 162 may be formed over the fourth buffer layer 124 and the first capping layer 144. The sacrificial layer 162 may be formed of the same material as the sacrificial layer 142’.

Referring to FIG. 5E, a planarization process may be performed until the sacrificial layer pattern 142” formed in the shield region 100S is exposed, so that the upper portion of the first capping layer 144 and the support layer 146 may be removed from the shield region 100S. For example, the second grid structure 140b formed in the shield region 100S may be formed in an open grid structure from which the entire top surface is removed.

Referring to FIG. 5F, the sacrificial layer 162 and the sacrificial layer pattern 142” may be removed through a plasma process, thereby forming an air layer 142 in the space previously occupied by the sacrificial layer pattern 142”. For example, an air layer 142 in which both the upper and side portions are covered by the first capping layer 144 may be formed in the pixel array 100P, and an air layer in which only the upper portion is opened may be formed in the shield region 100S.

The plasma process may be carried out using gas (e.g., O₂, N₂, H₂, CO, CO₂, or CH₄) including at least one of oxygen, nitrogen, or hydrogen. For example, if the O₂ plasma process is carried out, oxygen radicals (O*) may be combined with carbons of the sacrificial layer 162 and the sacrificial layer pattern 142” to generate CO or CO₂, thereby removing the sacrificial layer 162 and sacrificial layer pattern 142”. In this case, the sacrificial layer pattern 142” in the shield region 100S may easily react with the oxygen radicals (O*) through the area where the first capping layer 144 has been removed. If the first capping layer 144 is formed as a thin layer, the oxygen radicals may also pass through the first capping layer 144 and then flow into the sacrificial layer pattern 142” during the plasma process.

The CO or CO₂ generated during the removal of the sacrificial layer pattern 142” may be discharged outside through the position from which the capping layer 144 is removed. In addition, if the first capping layer 144 is formed as a thin layer, the CO or CO₂ may also be discharged outside through the first capping layer 144. Through this process, an air layer 142 may be formed in the space where the sacrificial layer pattern 142” was removed.

The support layer 146 formed over the sacrificial layer pattern 142” may support the first capping layer 144 during the removal of the sacrificial layer pattern 142”, so that the support layer 146 may prevent collapse of the first capping layer 134.

When the plasma process is performed in a state where the sacrificial layer pattern 142” is completely capped, the oxygen radicals are introduced through the first capping layer 144 and are combined with the sacrificial layer pattern 142”, and the generated gases must also escape to the outside through the first capping layer 144, so that the sacrificial layer pattern 142” is not easily removed. In addition, accumulation of generated gases may cause the first capping layer 144 to rupture (collapse).

In the present embodiment, after the grid structure 140 extends to the shield region 100S, the upper region of the grid structure 140b of the shield region 100S is opened, so that the removal of the sacrificial layer pattern 142” and the formation of the air layer 142 can be more effectively performed. In addition, this open structure may allow the gases (CO or CO₂) generated during the formation of the air layer 142 to be efficiently discharged, so that collapse or deformation of the grid structure 140 due to such gas accumulation can be prevented. As a result, the reliability of the grid structure 140 can be improved.

Referring to FIG. 5G, color filters 150 may be formed in the regions defined by the first grid structure 140a and the second grid structure 140b.

In addition, an overcoating layer (not shown) may be formed over the color filters 150 to remove a step difference between the color filters 150, and a microlens (not shown) may be formed over the overcoating layer.

Although FIGS. 5A-5G illustrate the example case where the first grid structure 140a and the second grid structure 140b are formed to have the same width as shown in FIG. 3, other implementations are also possible. Alternatively, as the mask pattern 161 to be formed in the shield region 100S in FIG. 5B may be formed with a greater width than the mask pattern 161 to be formed in the pixel array 100P, a second grid structure 140c having a larger width than the first grid structure 140a may be formed as shown in FIG. 4.

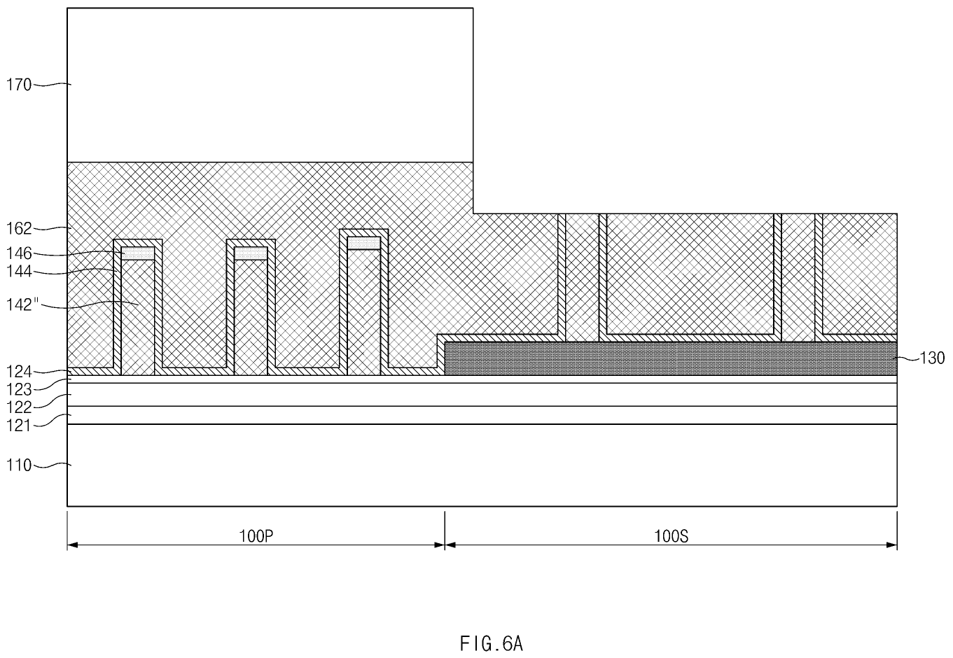

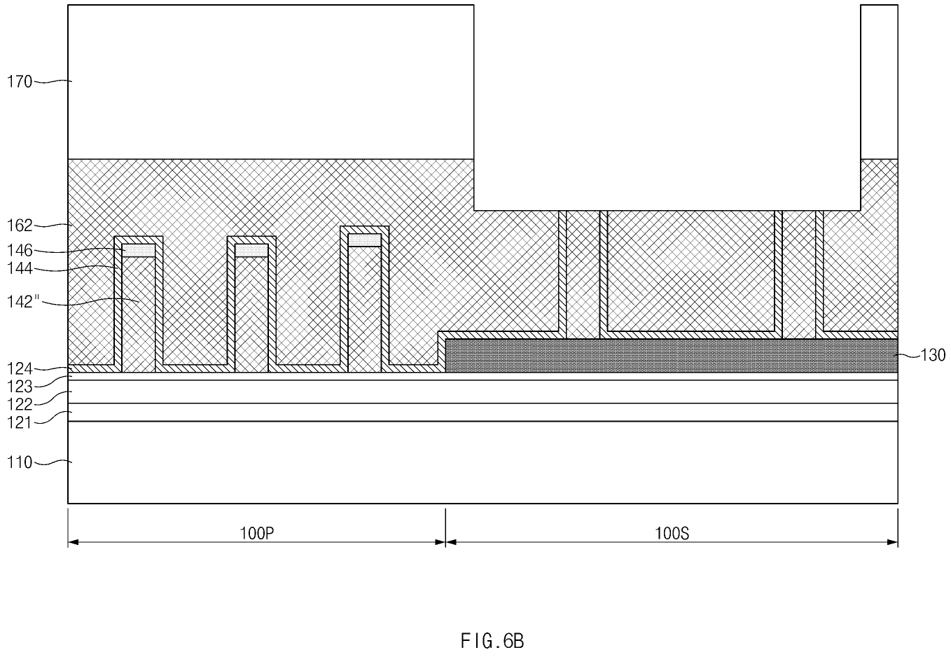

FIGS. 6A and 6B are cross-sectional views illustrating examples of another method for forming the structure shown in FIG. 3 based on some embodiments of the disclosed technology.

Referring to FIGS. 6A and 6B, an upper region of the first capping layer 144 and the support layer 146 in the shield region 100S may also be selectively removed through an etching process using a mask. For example, after performing the fabrication processes shown in FIGS. 5A-5E, a mask pattern 170 may be formed over the sacrificial layer 162 so that the mask pattern 170 covers the pixel array 100P while exposing (opening) the shield region 100S. In this case, as shown in FIG. 6A, the mask pattern 170 may expose (open) the entire shield region 100S. Alternatively, as shown in FIG. 6B, the mask pattern 170 may selectively expose (open) only a portion of the shield region 100S.

Although FIG. 6B illustrates the example case where the mask pattern 170 exposes (opens) only the area of the shield region 100S adjacent to the pixel array 100P for convenience of description, other implementations are also possible. Alternatively, the mask pattern 170 may also expose (open) only the edge region of the shield region 100S. In this case, the mask pattern 170 may partially open the shield region 100S in the form of a rectangular band shape surrounding the pixel array 100P.

Then, an etching process may be performed using the mask pattern 170 as an etch mask, the shield region 100S may be selectively etched to a preset depth. As a result, the upper region of the first capping layer 144 and the support layer 146 may be removed from the shield region 100S.

Thereafter, the fabrication processes described in FIGS. 5F and 5G may be performed.

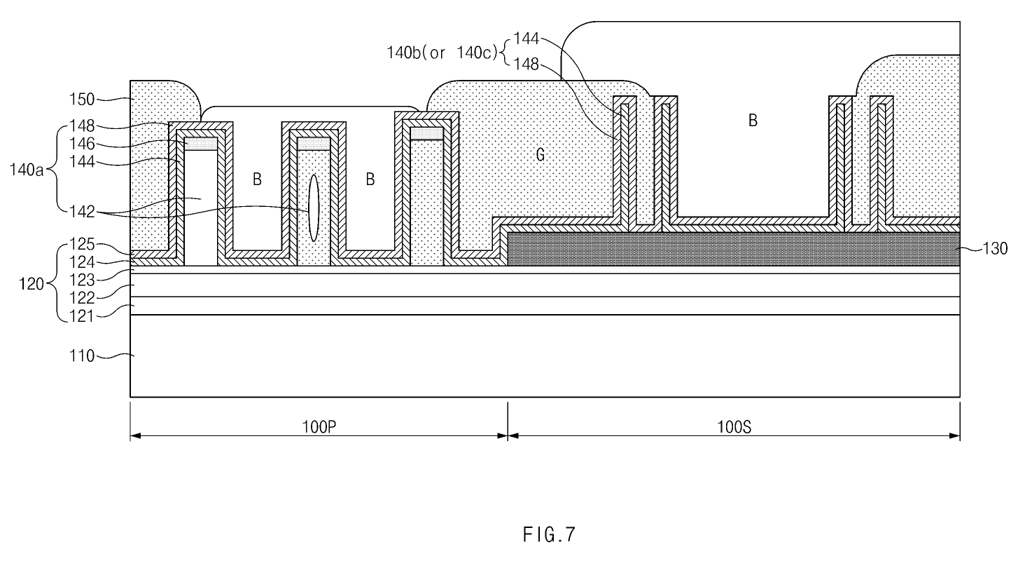

FIG. 7 is a cross-sectional view illustrating an example of a cross-section of the grid structure taken along the line X-X’ shown in FIG. 2 based on some embodiments of the disclosed technology.

Referring to FIG. 7, each of the first grid structure 140a and the second grid structure (140b or 140c) may include a capping layer having a multilayer structure. For example, the first grid structure 140b may include an air layer 142, a first capping layer 144, a second capping layer 148, and a support layer 146, and the second grid structure (140b or 140c) may include the first capping layer 144 and the second capping layer 148.

Compared to the embodiment shown in FIG. 3, in the embodiment of FIG. 7, the first grid structure 140a and the second grid structure (140b or 140c) may further include a second capping layer 148 surrounding the first capping layer 144. For example, the second capping layer 148 may be formed over the first capping layer 144 so that the second capping layer 148 contacts the first capping layer 144. The second capping layer 148 may include the same ULTO layer as the first capping layer 144. Alternatively, the second capping layer 148 may include a different insulation material from the first capping layer 144.

In a situation where the first capping layer 144 is formed as a thin layer, when the air layer 142 is formed or when a subsequent thermal process after formation of the air layer 142 is performed, expansion of the air layer 142 occurs, so that the first capping layer 144 may collapse (rupture). Therefore, since the second capping layer 148 is additionally formed over the first capping layer 144, the first grid structure 140a and the second grid structure (140b or 140c) may be formed to be more robust.

The buffer layer 120 may further include a fifth buffer layer 125 formed over the fourth buffer layer 124. The fifth buffer layer 125 may be formed of the same material as the second capping layer 148. Although the present embodiment illustrates that the fifth buffer layer 125 and the second capping layer 148 are shown separately for convenience of description, other implementations are also possible, and the fifth buffer layer 125 and the second capping layer 148 may also be formed simultaneously through the same process.

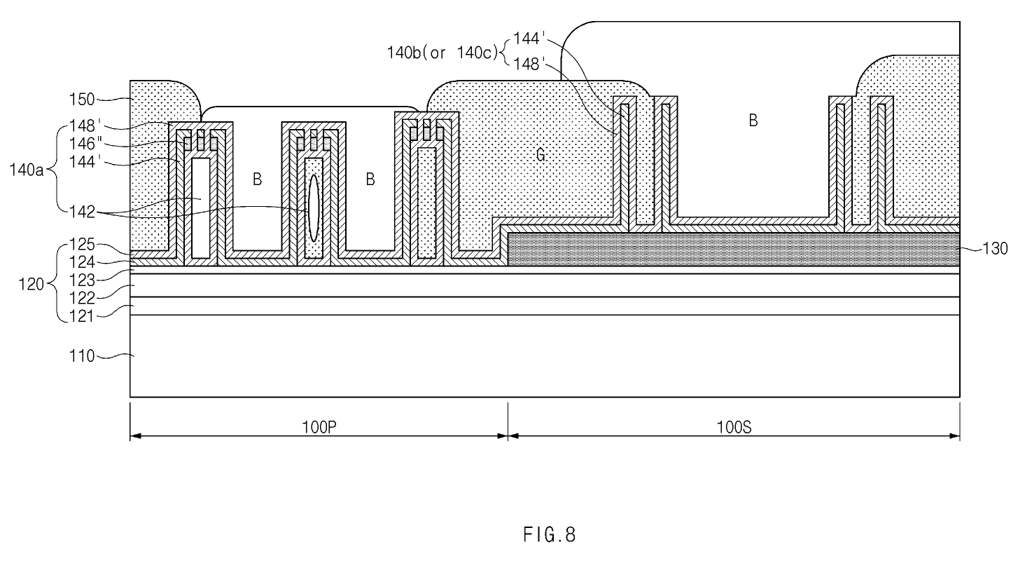

FIG. 8 is a cross-sectional view illustrating an example of a cross-section of the grid structure taken along the line X-X’ shown in FIG. 2 based on some embodiments of the disclosed technology. The following description of FIG. 8 will focus on the structural differences compared to the structure shown in FIG. 7.

Referring to FIG. 8, the first grid structure 140a may include an air layer 142, a first capping layer 144’, a second capping layer 148’, and a support layer 146’’.

The first capping layer 144’ and the support layer 146’’ may include through-holes, upper regions of which are penetrated. The through-holes may be formed by a direct self-assembly (DSA) process using a block copolymer. The first capping layer 144’ may include an ultra-low-temperature oxide (ULTO) layer, and the support layer 146’’ may include silicon oxynitride (SiON).

The second capping layer 148’ may be formed over an inner surface and an outer surface of the first capping layer 144’ while filling the through-holes in the first capping layer 144’ and the support layer 146’’. The second capping layer 148’ may be formed to completely surround the first capping layer 144’.

The first capping layer 144’ and the second capping layer 148’ may be formed of the same material. For example, each of the first capping layer 144’ and the second capping layer 148’ may include an ultra-low-temperature oxide (ULTO) layer. Alternatively, the first capping layer 144’ and the second capping layer 148’ may be formed of different materials. For example, the first capping layer 144’ may include an ultra-low-temperature oxide (ULTO) layer, and the second capping layer 148’ may include at least one of aluminum oxide (Al₂O₃), hafnium oxide (HfO₂), or silicon nitride (SiN).

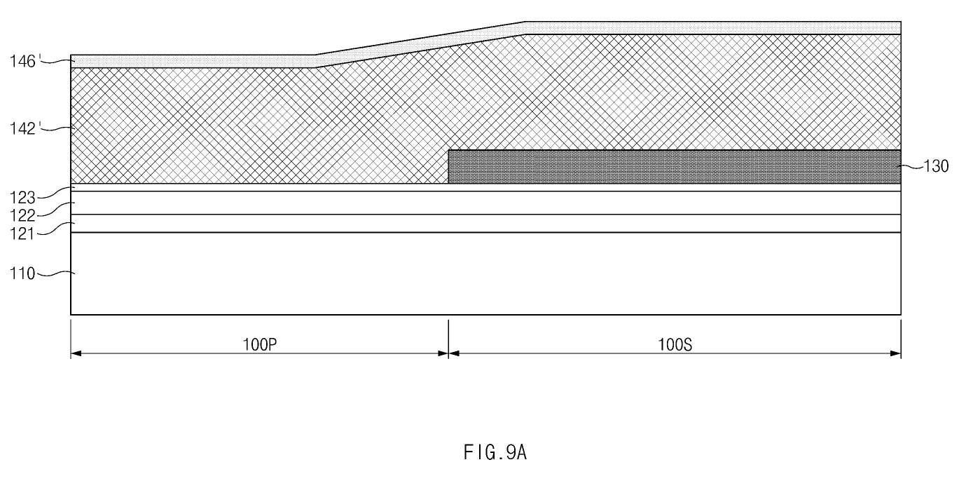

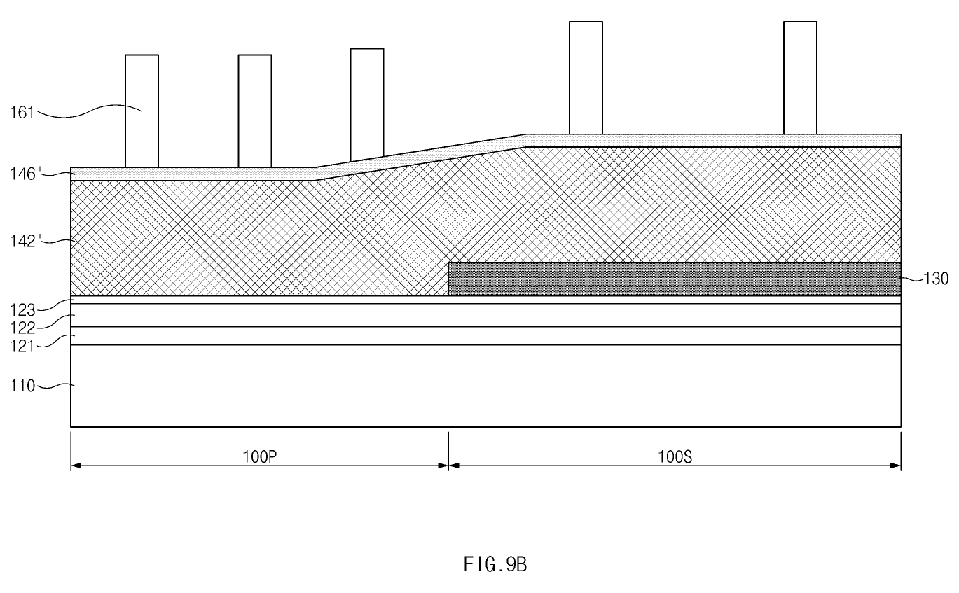

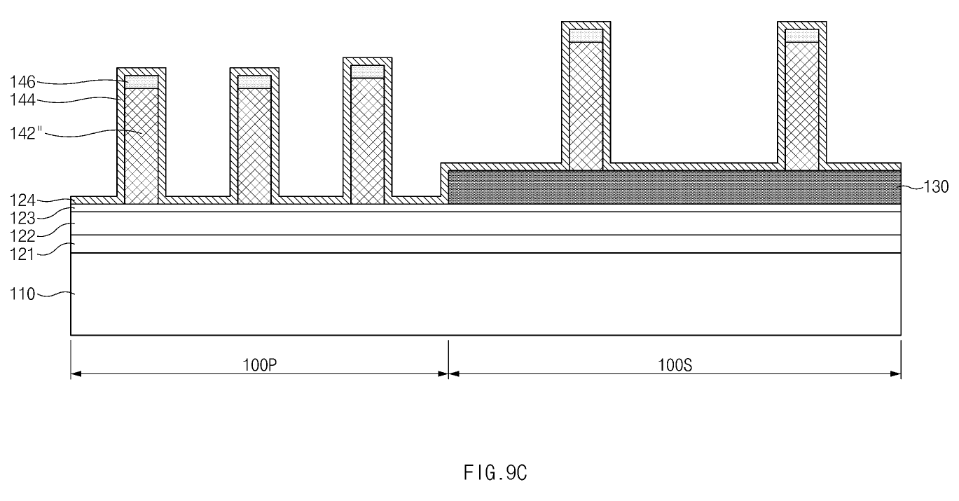

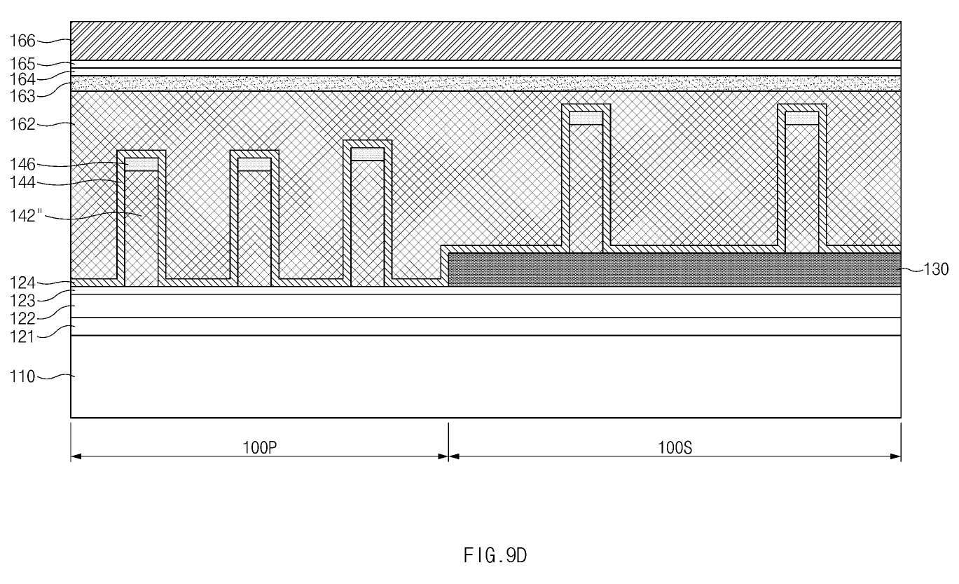

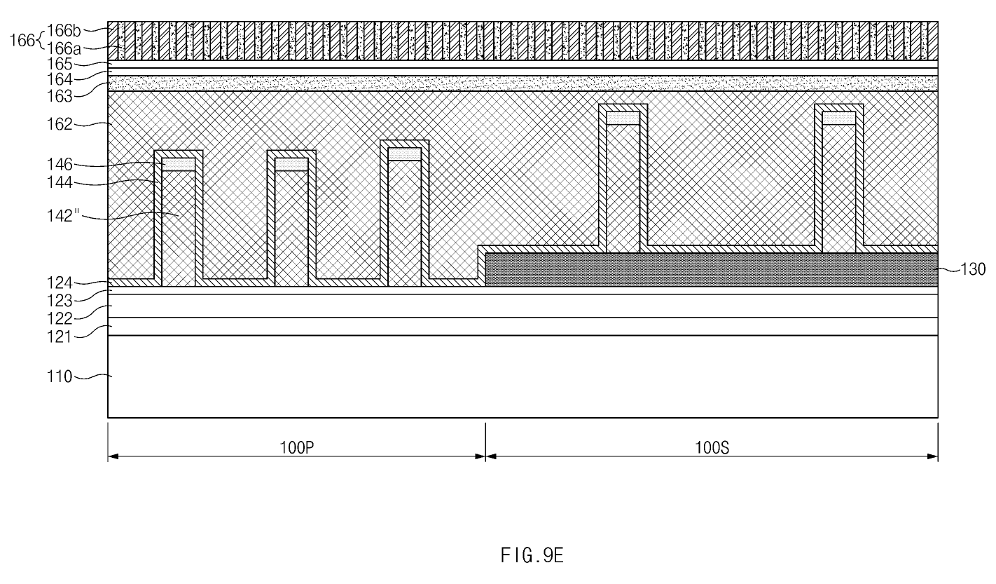

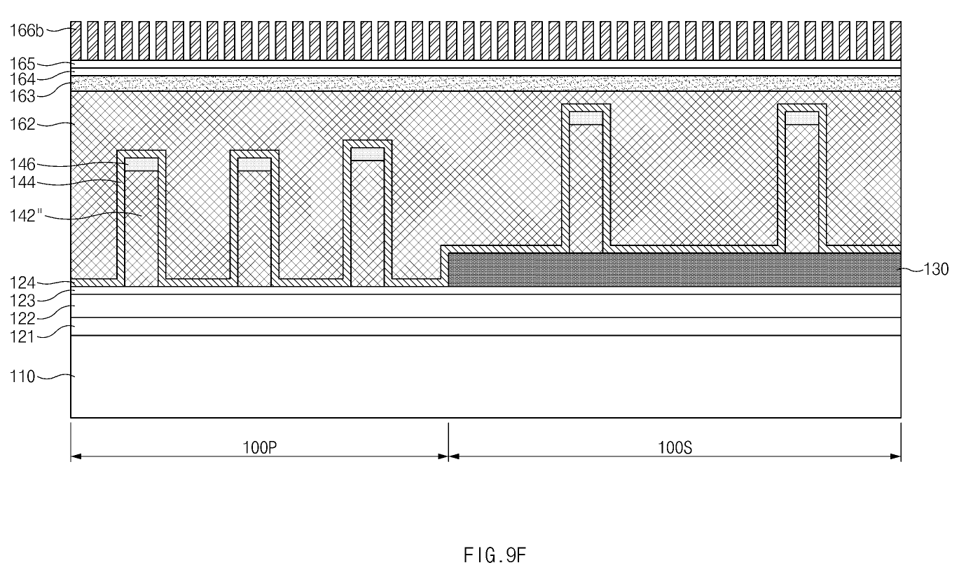

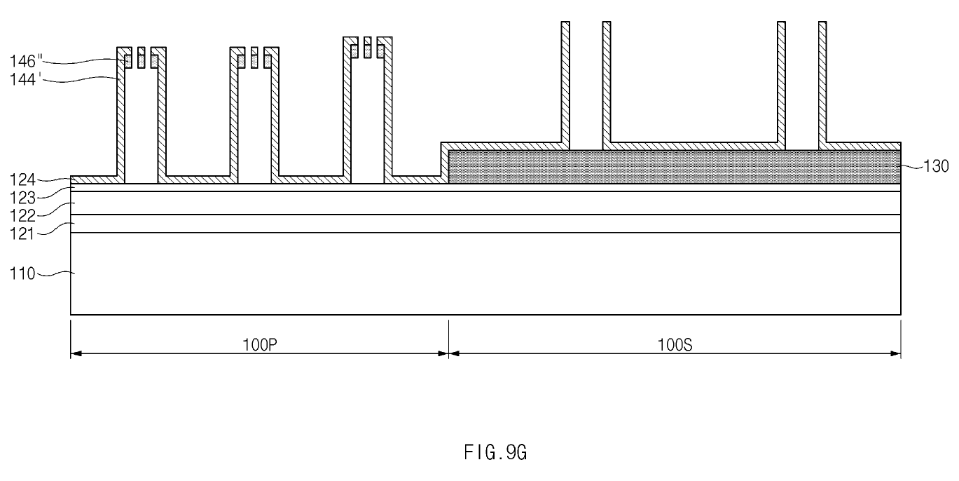

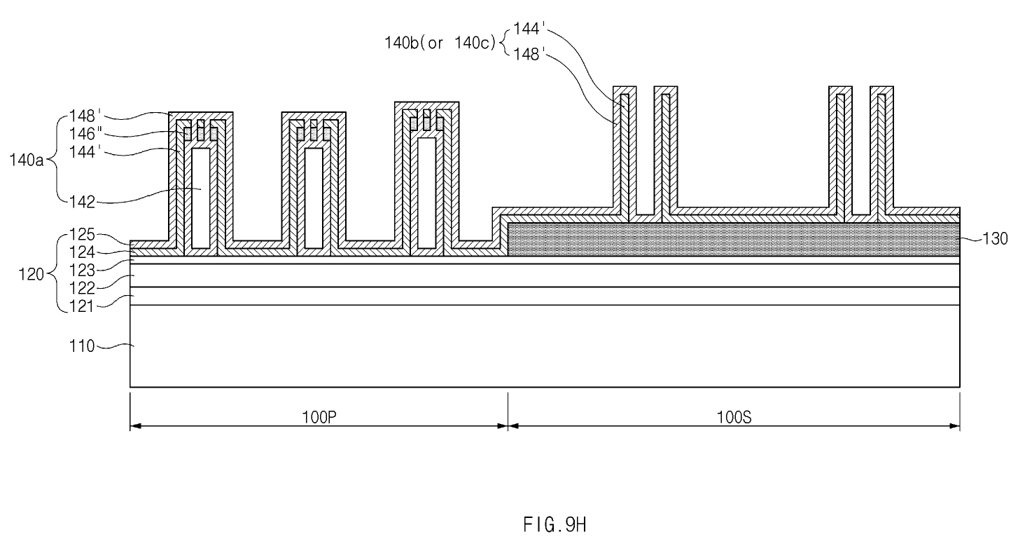

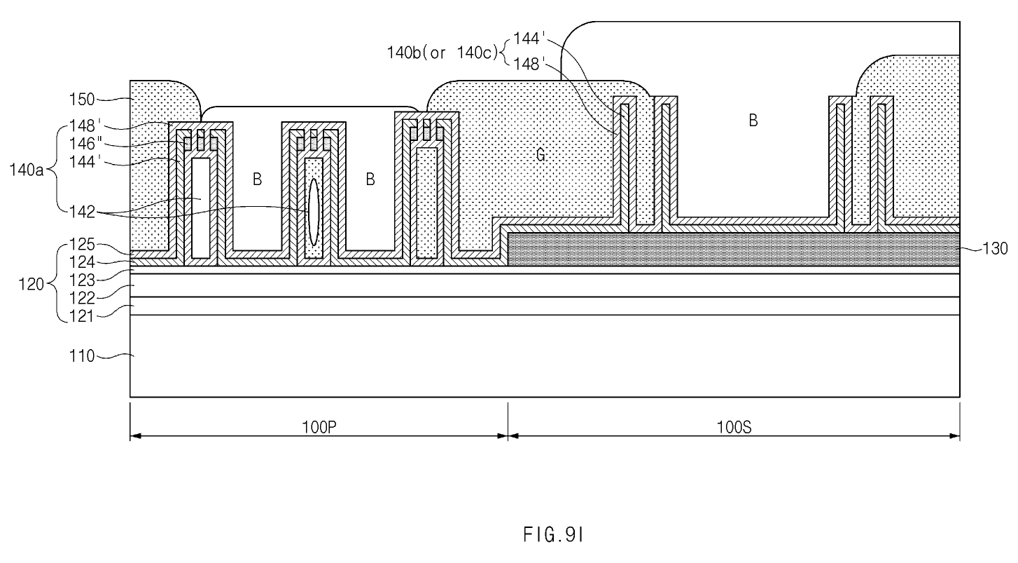

FIGS. 9A-9I are cross-sectional views illustrating examples of a method for forming the structure shown in FIG. 8 based on some embodiments of the disclosed technology.

Referring to FIG. 9A, first to third buffer layers (121~123) may be sequentially formed over the substrate 110 in which photoelectric conversion elements and pixel isolation structures are formed. In this case, the first buffer layer 121 may include a metal oxide such as aluminum oxide (Al₂O₃) or hafnium oxide (HfO₂). The second buffer layer 122 may include silicon oxide (SiO₂), and the third buffer layer 123 may include a nitride layer such as silicon nitride or silicon oxynitride.

Subsequently, after a metal layer is formed over the third buffer layer 123, the metal layer is patterned so that the metal layer remains only in the shield region 100S, resulting in formation of the light absorption layer 130.

A sacrificial layer 142’ may be formed over the third buffer layer 123 and the light absorption layer 130 in each of the pixel array 100P and the shield region 100S, and a support material layer 146’ may be formed over the sacrificial layer 142’. Due to a step difference caused by the light absorption layer 130, the sacrificial layer 142’ of the shield region 100S may be located higher than the sacrificial layer 142’ of the pixel array 100P. The sacrificial layer 142’ may include a spin-on carbon (SOC) layer containing carbon, and the support material layer 146’ may include silicon oxynitride (SiON).

Referring to FIG. 9B, a mask pattern 161 may be formed over the support material layer 146’ to define the regions where the first grid structure 140a and the second grid structure 140b are to be formed. In the same manner as in the grid structure 140 shown in FIGS. 2 or 4, the mask pattern 161 may be connected in a grid shape across both the pixel array 100P and the shield region 100S. The mask pattern 161 may include a photoresist pattern.

Referring to FIG. 9C, using the mask pattern 161 as an etch mask, the support material layer 146’ and the sacrificial layer 142’ may be sequentially etched, thereby forming the support layer 146 and the sacrificial layer pattern 142”.

Subsequently, a fourth buffer layer 124 and a first capping layer 144 may be formed to cover the third buffer layer 123, the light absorption layer 130, the sacrificial layer pattern 142”, and the support layer 146. Each of the fourth buffer layer 124 and the first capping layer 144 may include an ultra-low-temperature oxide (ULTO) layer. In the present embodiment, the fourth buffer layer 124 and the first capping layer 144 are shown separately for convenience of description, but the fourth buffer layer 124 and the first capping layer 144 may be formed simultaneously through the same process.

Referring to FIG. 9D, a sacrificial layer 162 may be formed over the first capping layer 144, and insulation layers (163, 164) may be sequentially formed over the sacrificial layer 162. At this time, the sacrificial layer 162 may include a carbon-containing SOC (Spin On Carbon) layer. The insulation layer 163 may include a silicon oxynitride layer (SiON). The insulation layer 164 may include a polysilicon layer.

Thereafter, a neutral layer 165 and a direct self-assembly (DSA) material layer 166 may be sequentially formed over the insulation layer 164.

The neutral layer 165 may be designed to induce pattern formation of the DSA material layer 166. The neutral layer 165 may serve to induce polymer blocks constituting a block co-polymer to be phase-separated into block domain portions that are alternately repeated in a cylinder shape or a lamellar shape. The neutral layer 165 may operate as an orientation control layer that controls orientation of the polymer blocks during the phase separation process in which the polymer blocks are re-ordered to form block domain portions, thereby causing the block domain portions to be alternately repeated.

The neutral layer 165 may be formed of a material having a similar affinity for each of the polymer block components constituting the block co-polymer. For example, the neutral layer 165 may include a random co-polymer in which different polymer components constituting the block co-polymer are randomly copolymerized. When a polystyrene-polymethyl methacrylate block copolymer (PS-b-PMMA) is used as a self-aligned block co-polymer, the neutral layer 165 may include a random co-polymer of polystyrene and polymethyl methacrylate (PS-b-PMMA) (i.e., random PS: PMMA (PS-r-PMMA)).

The DSA material layer 166 may include a block co-polymer in which the polymer blocks having two or more different structures are covalently bonded to form one polymer. For example, the DSA material layer 166 may include polymethyl methacrylate (PMMA) and polystyrene (PS). The DSA material layer 166 may be coated in a homogeneous phase mixed state using a spin coating method.

Referring to FIG. 9E, DSA patterning may be performed on the DSA material layer 166. For example, an N₂ annealing process may be performed on the DSA material layer 166.

The DSA material layer 166 may be phase-separated into a first polymer block component 166a and a second polymer block component 166b by the annealing process. When the DSA material layer 166 includes a block co-polymer, the DSA material layer 166 may be separated into PMMA (polymethylmethacrylate) and PS (polystyrene) by the annealing process. PMMA and PS may be self-aligned in various forms depending on a composition ratio.

The polymer block components that constitute the block co-polymer may have different mixing characteristics and different solubilities due to differences in chemical structures. The polymer components may be immiscibly separated from each other while being intermixed by annealing, and may be reordered, so that the polymer components can be phase-separated from each other.

Forming a microstructure of a specific shape through direct self-assembly (DSA) of the block co-polymer may be affected by physical and/or chemical characteristics of each block polymer. When a block co-polymer composed of two different polymers is self-assembled, the self-assembled structure of the block copolymer may be formed in various structures, such as a three-dimensional (3D) cubic and double helix structure, or a two-dimensional (2D) hexagonal packed column structure and a lamellar structure, depending on a volume ratio of each polymer block that constitutes the block co-polymer, the annealing temperature for phase separation, the size of a molecule of the block polymer, and the like.

Referring to FIG. 9F, the first polymer block component 166a may be selectively removed from the DSA material layer 166 separated into the first polymer block component 166a and the second polymer block component 166b.

For example, a metal-containing precursor may be injected into the DSA material layer 166 so that the metal-containing precursor can be selectively coupled (bound) to the first polymer block component 166a. The metal of the metal-containing precursor may include aluminum (Al). The metal-containing precursor may include tetramethylammonium (TMA). For example, TMA may be selectively coupled (bound) to PMMA.

By injecting such a metal-containing precursor, the metal may penetrate into the first polymer block component 166a, so that the first polymer block component 166a may be modified into the metal-containing first polymer block component. The metal-containing first polymer block component may have an etch selectivity with respect to the second polymer block component 166b. The first polymer block component 166a may be selectively removed using the etch selectivity.

Referring to FIG. 9G, the material layers (165, 164, 163, 162, 146, 144, 142″) may be etched using the DSA pattern containing the second polymer block component 166b as an etch mask. As a result, through-holes penetrating the first capping layer 144 and the support layer 146 may be formed in the pixel array 100P, and the upper region of the first capping layer 144 and the support layer 146 may be removed in the shield region 100S. The first capping layer 144 and the support layer 146 may be located much closer to the DSA pattern in the shield region 100S than in the pixel array 100P. As a result, when through-holes are formed in the pixel array 100P, the upper region of the first capping layer 144 and the support layer 146 may be removed from the shield region 100S. The through-holes may be formed to expose the first sacrificial layer pattern 142”.

Subsequently, the sacrificial layer 162 and the sacrificial layer pattern 142” may be removed through a plasma process. In this case, the plasma process may be carried out using gas (e.g., O₂, N₂, H₂, CO, CO₂, or CH₄) including at least one of oxygen, nitrogen, or hydrogen. For example, if the O₂ plasma process is carried out, oxygen radicals (O*) may flow into the sacrificial layer 162 and the sacrificial layer pattern 142”, and the oxygen radicals (O*) may be combined with carbons of the sacrificial layer 162 and the sacrificial layer pattern 142”. At this time, in the pixel array 100P, the sacrificial layer pattern 142” located in the first capping layer 144’ is also exposed through the through-holes, so that the sacrificial layer pattern 142” may be more easily coupled to the oxygen radicals.

The carbon in the sacrificial layer 162 and the carbon in the sacrificial layer pattern 142” may be combined with oxygen radicals to form CO or CO₂, so that such carbons can be removed. In this case, the generated CO or CO₂ may be easily discharged outside through the through-holes formed in the pixel array 100P and the open regions formed in the shield region 100S. In this way, according to the present embodiment, since the sacrificial layer pattern 142” in the pixel array 100P is also exposed to the outside during the plasma process, the sacrificial layer pattern 142” can be more easily removed, so that a wider space in which the air layer 142 is formed can be secured.

Referring to FIG. 9H, the first grid structure 140a and the second grid structure (140b or 140c) may be formed by depositing the insulation layer (e.g., an oxide layer) over the inner surface and the outer surface of the first capping layer 144’ so that the through-holes can be filled with the insulation layer.

For example, an insulation layer may be deposited using an atomic layer deposition (ALD) process and/or a chemical vapor deposition (CVD) process to fill the through-holes in the first capping layer 144’ and the support layer 146’’. During the process of filling the through-holes, the insulation layer may also be deposited over the inner and outer surfaces of the first capping layer 144’, resulting in formation of the second capping layer 148’. Additionally, the insulation layer may be deposited over the fourth buffer layer 124, resulting in formation of the fifth buffer layer 125.

The second capping layer 148’ may be made of the same material (ULTO) as the first capping layer 144’. Alternatively, the second capping layer 148’ may be made of a different material from the first capping layer 144’. For example, the second capping layer 148’ may include an aluminum oxide (Al₂O₃) layer, a hafnium oxide (HfO₂) layer, or a silicon nitride (SiN) layer.

Referring to FIG. 9I, color filters 150 may be formed in regions defined by the first grid structure 140a and the second grid structure 140b.

In addition, an overcoating layer (not shown) may be formed over the color filters 150 to remove a step difference between the color filters 150, and a microlens (not shown) may be formed over the overcoating layer.

As is apparent from the above description, the image sensing device based on some embodiments of the disclosed technology can improve the reliability of a grid structure including an air layer.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device, comprising:
a substrate;
a pixel array supported by the substrate and configured to include pixels;
a shield region supported by the substrate and disposed outside the pixel array;
a plurality of color filters disposed over the substrate;
a first grid structure disposed between color filters in the pixel array;
a second grid structure connected to the first grid structure and disposed between color filters in the shield region; and
a light absorption layer disposed between the substrate and the second grid structure in the shield region,
wherein
the second grid structure includes an open grid region having an upper portion open to expose an internal region of the second grid structure.

2. The image sensing device according to claim 1, wherein the first grid structure includes an air layer; and
a first capping layer formed to surround a top surface and side surfaces of the air layer.

3. The image sensing device according to claim 2, wherein:
the second grid structure is free of the air layer, and includes the first capping layer having portions formed as sidewalls spaced apart from each other by a predetermined distance.

4. The image sensing device according to claim 3, wherein each of the first gird structure and the second grid structure further includes:
a second capping layer surrounding the first capping layer.

5. The image sensing device according to claim 1, wherein the first grid structure includes:
an air layer;
a first capping layer including a plurality of through-holes and configured to surround a top surface and side surfaces of the air layer; and a second capping layer configured to fill the plurality of through-holes and surround the first capping layer.

6. The image sensing device according to claim 5,
wherein the second grid structure is free of the air layer, and includes portions formed as sidewalls spaced apart from each other by a predetermined distance, and
wherein the second capping layer surrounds the first capping layer.

7. The image sensing device according to claim 1, wherein:
an entire region of the second grid structure is formed as the open grid region.

8. The image sensing device according to claim 1, wherein:
only a partial region of the second grid structure includes the open grid region.

9. The image sensing device according to claim 8, wherein:
the open grid region is formed in a band shape surrounding the pixel array.

10. The image sensing device according to claim 1, wherein:
the first grid structure and the second grid structure have different widths from each other.

11. The image sensing device according to claim 1, wherein:
an internal region of the second grid structure is filled with a same material as one of the plurality of color filters.

12. The image sensing device according to claim 1, wherein:
the first grid structure includes:
first patterns extending parallel to each other in a first direction; and
second patterns extending parallel to each other in a second direction perpendicular to the first direction,
the second grid structure is connected to some of the first patterns and the second patterns.

13. The image sensing device according to claim 12, wherein:
the second grid structure is connected to either even-numbered patterns or odd-numbered patterns of the first patterns and the second patterns.

14. A method for manufacturing an image sensing device comprising:
forming a light absorption layer in a shield region supported by a substrate including a pixel array, the shield region disposed outside the pixel array;
forming a first sacrificial layer over the substrate and the light absorption layer;
forming a first mask pattern over the first sacrificial layer to define a region in which a grid structure is to be formed;
etching the first sacrificial layer using the first mask pattern as an etch mask to form a sacrificial layer pattern in each of the pixel array and the shield region;
forming a first capping layer to cover the sacrificial layer pattern;
exposing the sacrificial layer pattern by selectively removing an upper portion of the first capping layer located in the shield region; and
removing the sacrificial layer pattern.

15. The method according to claim 14, wherein the exposing the sacrificial layer pattern includes:
forming a second sacrificial layer over the first capping layer; and
performing a planarization process to remain the first capping layer in the pixel array and remove an upper region of the first capping layer disposed over the light absorption layer in the shield region.

16. The method according to claim 14, wherein the exposing the sacrificial layer pattern includes:
forming a second sacrificial layer over the first capping layer;
forming a second mask pattern over the second sacrificial layer, the second mask pattern covering the pixel array and allowing at least a portion of the shield region to be open; and
removing the second sacrificial layer and a portion of the first capping layer in the shield region using the second mask pattern as an etch mask.

17. The method according to claim 16, wherein the forming the second mask pattern allows an entirety of the shield region to open or
only a portion of the shield region to open and have a band shape surrounding the pixel array.

18. The method according to claim 14, wherein the exposing the sacrificial layer pattern includes:
forming a second sacrificial layer over the first capping layer;
forming a direct self-assembly (DSA) pattern over the second sacrificial layer; and
removing the second sacrificial layer and a portion of the first capping layer using the DSA pattern as an etch mask.

19. The method according to claim 18, wherein the removing a portion of the first capping layer includes:
obtaining a difference in distance between the DSA pattern and the first capping layer in each of the pixel array and the shield region;
forming through-holes penetrating the upper portion of the first capping layer in the pixel array using the distance difference; and
completely removing the upper portion of the first capping layer in the shield region using the distance difference.

20. The method according to claim 18, wherein the forming the DSA pattern includes:
forming a neutral layer and a DSA material layer over the second sacrificial layer;
separating the DSA material layer into a first polymer block component and a second polymer block component by performing annealing on the DSA material layer; and
selectively removing the first polymer block component.
